(19) United States
(12) Patent Application Publication
(10) Pub. No.: US 2022/0020596 A1
(43) Pub. Date: Jan. 20, 2022

(54) ETCHING PROCESSING APPARATUS, QUARTZ MEMBER AND PLASMA PROCESSING METHOD

(71) Applicant: Tokyo Electron Limited, Tokyo (JP)

(72) Inventors: Toshihiko KIKUCHI, Miyagi (JP); Nobuyuki NAGAYAMA, Miyagi (JP)

(21) Appl. No.: 17/305,471

(22) Filed: Jul. 8, 2021

(30) Foreign Application Priority Data
Jul. 17, 2020 (JP) 2020-123270

(51) Int. Cl. H01L 21/311; H01L 21/3065; H01J 37/32

(52) U.S. Cl. CPC H01L 21/31116; H01L 21/3065; H01J 2237/334; H01J 37/32449; H01J 2237/3321; H01J 37/32642

(57) ABSTRACT

An etching processing apparatus includes a stage configured to receive a substrate, a chamber configured to contain the stage, and a plasma generator configured to generate plasma in the chamber. An annular quartz member is disposed in a space in which the plasma is generated. The annular quartz member includes a surface facing the space. A coating film covers the surface of the quartz member. The coating film is made of a material other than quartz, and has a thickness of 10 nm or more and less than 800 nm.

### CROSS-REFERENCE TO RELATED APPLICATION

The present application is based on and claims priority to Japanese Priority Application No. 2020-123270 filed on Jul. 17, 2020, the entire contents of which are hereby incorporated herein by reference.

### BACKGROUND OF THE INVENTION

### 1. Field of the Invention

The present disclosure relates to an etching processing apparatus, a quartz member and a plasma processing method.

### 2. Description of the Related Art

An etching processing apparatus is known that supplies a process gas into a chamber, forms plasma from the process gas, and etches a substrate. A quartz member is provided in the chamber. On the surface of the quartz member in the chamber, a substance produced by the etching process is deposited. The deposited substance's peeling off from the quartz member causes a particle, which may adhere to the surface of the substrate and the like.

Japanese Laid-Open Patent Application Publication No. 2003-174017 discloses a method of processing a quartz member for a plasma processing apparatus. The method processes a surface of a quartz member that is mounted on a plasma processing apparatus for performing a predetermined process on an object to be processed with plasma excited in a process chamber and that has an exposed face exposing to the process chamber. The method features a wet etching process on the exposed surface of the quartz member with an acid after processing the surface with an abrasive grain of a first grain size.

### SUMMARY OF THE INVENTION

In one aspect, the present disclosure provides an etching processing apparatus, a quartz member, and a plasma processing method for inhibiting the generation of particles.

According to one embodiment of the present disclosure, there is provided an etching processing apparatus. The etching processing apparatus includes a stage configured to receive a substrate, a chamber configured to contain the stage, and a plasma generator configured to generate plasma in the chamber. An annular quartz member is disposed in a space in which the plasma is generated. The annular quartz member includes a surface facing the space. A coating film covers the surface of the quartz member. The coating film is made of a material other than quartz, and has a thickness of 10 nm or more and less than 800 nm.

### BRIEF DESCRIPTION OF THE DRAWINGS

FIG. 1 is a schematic cross-sectional view illustrating an example of an etching processing apparatus according to the present embodiment;

FIG. 2 is a perspective view of a cover ring according to the present embodiment;

FIG. 3 is an example of a flowchart illustrating manufacture and operation of a cover ring according to the present embodiment.

FIGS. 4A and 4B are examples of schematic cross-sectional views of a cover ring when the cover ring according to the present embodiment is manufactured;

FIGS. 5A to 5C are examples of schematic cross-sectional views of a cover ring in operation according to the present embodiment;

FIG. 6 is an example of a schematic cross-sectional view of a cover ring when the cover ring according to a reference example is manufactured;

FIGS. 7A and 7B are examples of schematic cross-sectional views of a cover ring in operation according to a reference example;

FIGS. 8A and 8B are examples of cross-sectional views of a cover ring after a reaction by-product film is deposited;

FIG. 9 is an example of a graph explaining the number of dusts emitted from a cover ring according to the present embodiment and a reference example;

FIGS. 10A and 10B are examples of cross-sectional views of a cover ring after a reaction by-product film is deposited; and

FIG. 11 is an example of a graph showing consumption rates due to plasma.

### DETAILED DESCRIPTION OF THE PREFERRED EMBODIMENTS

Hereinafter, embodiments of the present disclosure will be described in detail with reference to the drawings. In each drawing, the same components are indicated by the same reference numerals and overlapping descriptions may be omitted.

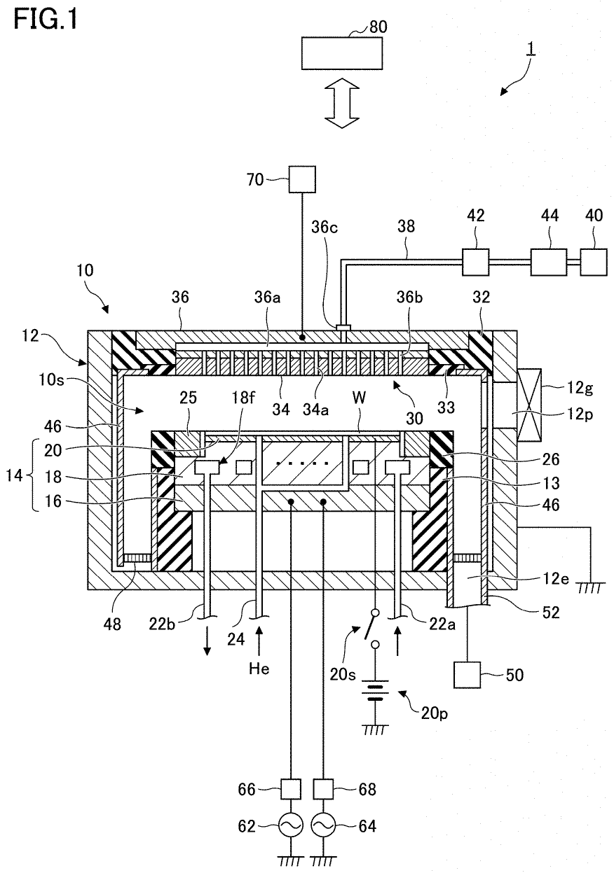

An etching processing apparatus 1 according to the present embodiment will be described with reference to FIG. 1. FIG. 1 is a cross-sectional view illustrating an example of the etching processing apparatus 1 according to the present embodiment. In the following description, the etching processing device 1 is described as a plasma etching device for etching an insulating film (SiO₂ film, SiN film) formed on the substrate W, for example.

The etching processing device 1 includes a chamber 10. The chamber 10 provides an inner space 10s therein. The chamber 10 includes a chamber body 12. The chamber body 12 has a generally cylindrical shape. The chamber body 12 is formed, for example, of aluminum. A corrosion resistant film is provided on the inner wall of the chamber body 12. The film may be a ceramic such as aluminum oxide, yttrium oxide and the like.

A passage 12p is formed in a side wall of the chamber body 12. A substrate W is conveyed between the inner space 10s and the outside of the chamber 10 through the passage 12p. The passage 12p is opened and closed by a gate valve 12g provided along the side wall of the chamber body 12.

A support 13 is provided on the bottom of the chamber body 12. The support 13 is formed of an insulative material. The support 13 has a generally cylindrical shape. The support 13 extends upwardly from the bottom of the chamber body 12 in the inner space 10s. The support 13 has a stage 14 on the top. The stage 14 is configured to support the substrate W in the inner space 10s.

The stage 14 has a lower electrode 18 and an electrostatic chuck 20. The stage 14 may further include an electrode plate 16. The electrode plate 16 is formed of a conductor, such as aluminum, and has an approximately disk shape. The lower electrode 18 is provided on the electrode plate 16. The lower electrode 18 is formed of a conductor, such as aluminum, and has an approximately disk shape. The lower electrode 18 is electrically connected to the electrode plate 16.

An electrostatic chuck 20 is provided on the lower electrode 18. A substrate W is mounted on the top surface of the electrostatic chuck 20. The electrostatic chuck 20 has a body and an electrode.

The body of the electrostatic chuck 20 has an approximately disk shape and is formed of a dielectric material. The electrode of the electrostatic chuck 20 is a membranous electrode provided within the body of the electrostatic chuck 20. The electrode of the electrostatic chuck 20 is connected to a DC power supply 20p via a switch 20s. When a voltage from the DC power supply 20p is applied to the electrode of the electrostatic chuck 20, an electrostatic attracting force is generated between the electrostatic chuck 20 and the substrate W. The electrostatic attraction holds the substrate W to the electrostatic chuck 20.

An edge ring 25 is disposed on the periphery of the lower electrode 18 to surround the edge of the substrate W. The edge ring 25 improves the uniformity across the substrate surface of the plasma process for the substrate W. The edge ring 25 may be formed of silicon, silicon carbide, quartz, or the like.

A cover ring 26 is disposed on the outer periphery of the edge ring 25 to surround the edge ring 25. The cover ring 26 is made of an insulator such as quartz. The cover ring 26 protects the top surface of the support 13 and the side wall of the bottom electrode 18 from plasma. The cover ring 26 is configured to be interchangeable.

A flow passage 18f is disposed within the lower electrode 18. A heat exchange medium (e.g., refrigerant) is supplied to the flow passage 18f from a chiller unit (which is not illustrated) disposed outside the chamber 10 through a pipe 22a. The heat exchange medium supplied to the flow passage 18f is returned to the chiller unit via a pipe 22b. In the etching processing apparatus 1, the temperature of the substrate W placed on the electrostatic chuck 20 is adjusted by heat exchange between the heat exchange medium and the lower electrode 18.

The etching processing apparatus 1 includes a gas supply line 24. The gas supply line 24 supplies heat transfer gas (for example, He gas) from a heat transfer gas supply mechanism to a space between the top surface of the electrostatic chuck 20 and the back surface of the substrate W.

The etching processing apparatus 1 further includes an upper electrode 30. The upper electrode 30 is located above the stage 14. The upper electrode 30 is supported at an upper portion of the chamber body 12 via members 32 and 33. The members 32 and 33 are formed of an insulating material. The upper electrode 30 and the members 32, 33 close the upper opening of the chamber body 12. The member 33 is disposed on the outer periphery of the ceiling plate 34 to surround the ceiling plate 34. The member 33 is exposed to the inner space 10s and is made of an insulator such as quartz. By forming the member 32 and the member 33 as separate parts, the plasma consuming member 33 can be replaced.

The upper electrode 30 may include the ceiling plate 34 and a support 36. The lower surface of the ceiling plate 34 is the lower surface on the inner space 10s side, and defines the inner space 10s. The ceiling plate 34 may be formed of a low resistance conductor or semiconductor with low Joule heat generation. The ceiling plate 34 has a plurality of gas discharge holes 34a through the ceiling plate 34 in a thickness direction.

The support 36 removably supports the ceiling plate 34. The support 36 is formed of an electrically conductive material such as aluminum. A gas diffusion chamber 36a is disposed inside the support 36. The support 36 has a plurality of gas holes 36b extending downwardly from the gas diffusion chamber 36a. The plurality of gas holes 36b each communicates with a plurality of gas discharge holes 34a. A gas inlet 36c is formed in the support 36. The gas inlet 36c is connected to the gas diffusion chamber 36a. A gas supply line 38 is connected to the gas inlet 36c.

A valve group 42, a flow controller group 44, and a gas source group 40 are connected to the gas supply line 38. The gas source group 40, the valve group 42, and the flow controller group 44 constitute the gas supply unit. The gas source group 40 includes a plurality of gas sources. The valve group 42 includes a plurality of open and close valves. The flow controller group 44 includes a plurality of flow controllers. Each of the plurality of flow controllers of the flow controller group 44 is a mass flow controller or a pressure controlling type flow controller. Each of the plurality of gas sources of the gas source group 40 is connected to the gas supply line 38 via a corresponding open and close valve of the valve group 42 and a corresponding flow controller of the flow controller group 44.

In the etching processing apparatus 1, a shield 46 is removably disposed along the inner wall surface of the chamber body 12 and the outer periphery of the support 13. Thus, the shield 46 is configured to be replaceable. The shield 46 prevents the reaction by-products from adhering to the chamber body 12. The shield 46 is, for example, configured by forming a corrosion resistant film on the surface (inner circumference) of a matrix formed of aluminum. The corrosion resistant film can be formed of ceramics such as aluminate or yttrium oxide.

A baffle plate 48 is disposed between the support 13 and the side wall of the chamber body 12. The baffle plate 48 is, for example, configured by forming a corrosion resistant film (a film such as yttrium oxide) on the surface of a matrix formed of aluminum. A plurality of through-holes is formed in the baffle plate 48. An exhaust port 12e is disposed below the baffle plate 48 and at the bottom of the chamber body 12. An exhaust device 50 is connected to the exhaust port 12e through an exhaust pipe 52. The exhaust device 50 includes a pressure regulating valve, and a vacuum pump such as a turbomolecular pump.

The etching processing apparatus 1 includes a first radio frequency power source 62 and a second radio frequency power source 64. The first radio frequency power source 62 is a power source that generates first radio frequency power. The first radio frequency power has a frequency suitable for generating a plasma. The frequency of the first radio frequency power is, for example, a frequency in the range of 27 MHz to 100 MHz. The first radio frequency power source 62 is connected to the lower electrode 18 via a matching box 66 and an electrode plate 16. The matching box 66 includes circuitry for matching the output impedance of the first radio frequency power source 62 to the impedance of the load side (on the bottom electrode 18 side). The first radio frequency power source 62 may be connected to the upper electrode 30 via the matching box 66. The first radio frequency power source 62 comprises an example of a plasma generator.

The second radio frequency power source 64 is a power source that generates the second radio frequency power. The second radio frequency power has a frequency lower than the frequency of the first radio frequency power. When the second radio frequency power is used in conjunction with the first radio frequency power, the second radio frequency power is used as the bias radio frequency power to attract ions to the substrate W. The frequency of the second radio frequency power is, for example, a frequency in the range of 400 kHz to 13.56 MHz. The second radio frequency power source 64 is connected to the lower electrode 18 via a matching box 68 and an electrode plate 16. The matching box 68 includes circuitry for matching the output impedance of the second radio frequency power source 64 to the impedance on the load side (lower electrode 18).

It should be noted that plasma may be generated using a second radio frequency power, that is, only a single radio frequency power, without using a first radio frequency power. In this case, the frequency of the second radio frequency power may be greater than 13.56 MHz, for example 40 MHz. The etching processing apparatus 1 may not include the first radio frequency power source 62 and the matching box 66. The second radio frequency power source 64 constitutes an example of a plasma generator.

In the etching processing apparatus 1, a gas is supplied from the gas supply unit to the inner space 10s to produce plasma. Also, the first radio frequency power and/or the second radio frequency power are supplied to generate a radio frequency electric field between the upper electrode 30 and the lower electrode 18. The generated radio frequency electric field produces plasma.

The etching processing apparatus 1 includes a power supply source 70. The power supply source 70 is connected to the upper electrode 30. The power supply source 70 applies a voltage to the upper electrode 30 to attract positive ions present in the inner space 10s to the ceiling plate 34.

The etching processing apparatus 1 may further comprise a controller 80. The controller 80 may be a computer including a processor, a storage unit such as a memory, an input device, a display device, an input and output interface of a signal, and the like. The controller 80 controls each part of the etching processing device 1. In the controller 80, an input device may be used to perform an input operation of a command for an operator to manage the etching processing apparatus 1. In the controller 80, the operation status of the etching processing device 1 can be visually displayed by the display device. Further, a control program and recipe data are stored in the storage unit. The processor executes the control program to execute various processes in the etching processing apparatus 1. The processor executes the control program and controls each portion of the etching processing apparatus 1 according to recipe data.

An example of the operation of the etching processing apparatus 1 will be described. An insulating film (SiO₂ film, SiN film and the like) as a film to be etched is formed on the substrate W. A mask having an opening is formed on the insulating film.

The controller 80 controls the gas source group 40, the valve group 42, and the flow controller group 44 to supply etching gas and argon gas from the gas holes 36b to the inner space 10s. A fluorocarbon or a hydrofluorocarbon is used as an etching gas. The fluorocarbon is, for example, CF₄, C₄F₆, and C₄F. The hydrofluorocarbon is, for example, CHF₃, and CH₂F₂. The controller 80 also controls the first radio frequency power source 62 to supply the first radio frequency power to the lower electrode 18 for generating plasma. The controller 80 also controls the second radio frequency power source 64 to supply the second radio frequency power to the lower electrode 18 for attracting ions to the substrate W.

This etches the insulating film through the mask by the plasma generated in the inner space 10s. The plasma generated in the inner space 10s consumes the edge ring 25, the cover ring 26, the member 33, the shield 46, and the like.

Also, when the insulating film is etched, a reaction by-product is generated. Examples of reaction byproducts include fluorocarbons and hydrocarbons. The reaction by-product is discharged from the inner space 10s by the exhaust device 50. A portion of the reaction by-product adheres to the edge ring 25, the cover ring 26, the member 33, the shield 46, and the like.

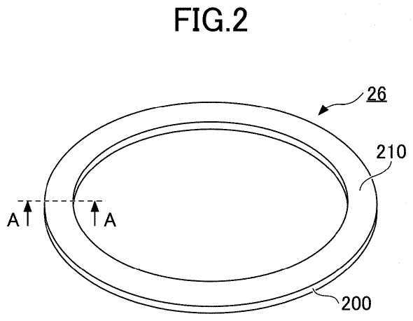

Next, the cover ring 26 according to this embodiment will be further described with reference to FIGS. 2 to 5C. FIG. 2 is a perspective view of a cover ring 26 in accordance with the present embodiment.

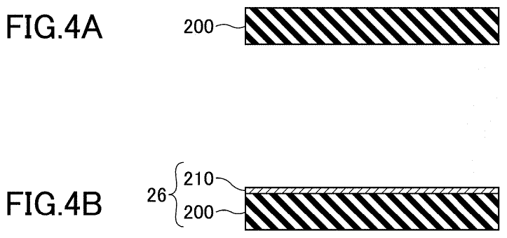

The cover ring 26 is an annular member disposed around the substrate W. The cover ring 26 has a base member 200 and a coating film 210, as illustrated in FIG. 4B.

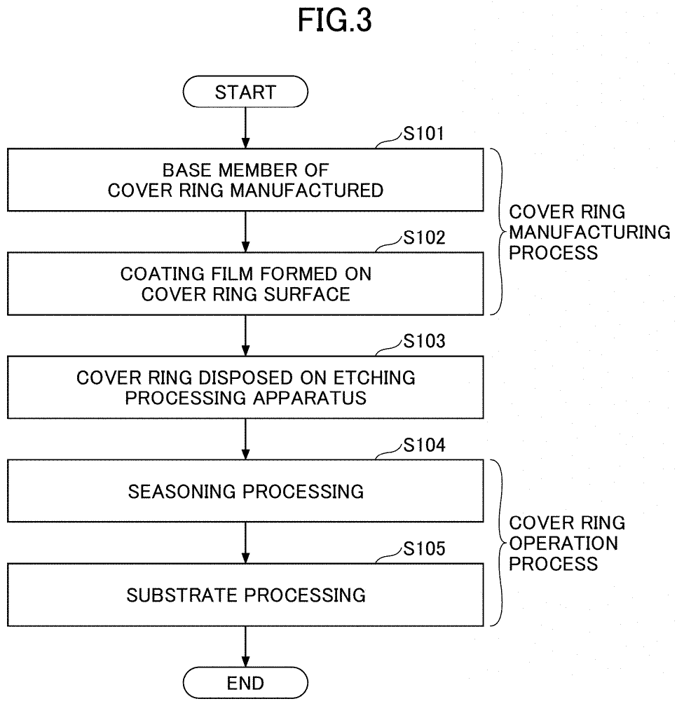

FIG. 3 is an example of a flowchart illustrating manufacture and operation of a cover ring 26 in accordance with the present embodiment.

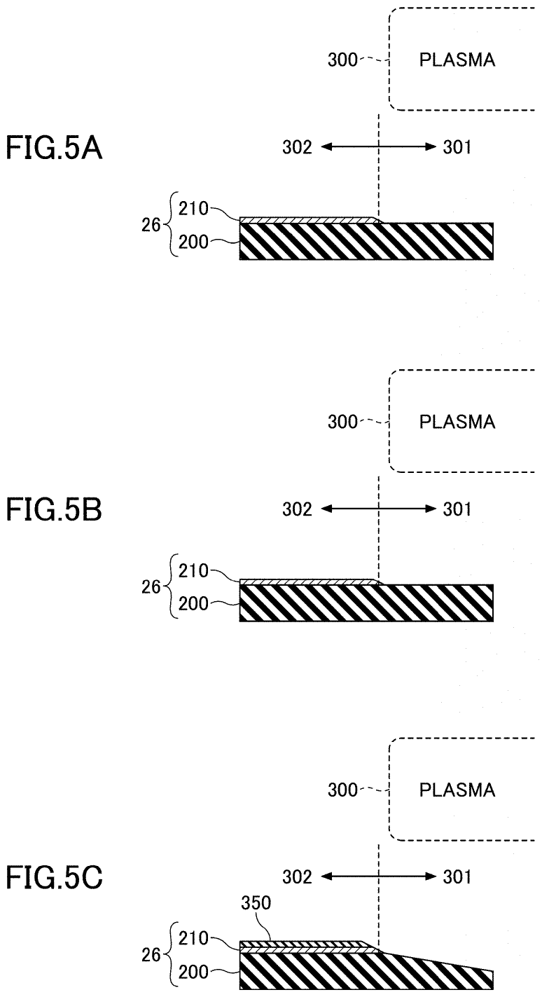

FIGS. 4A and 4B are an example of an A-A cross-sectional view of a cover ring 26 when the cover ring 26 is manufactured in accordance with the present embodiment. FIGS. 5A to 5C are an example of an A-A cross-sectional view of the cover ring 26 in operation according to the present embodiment.

In step S101, a base member 200 of a quartz cover ring 26 is manufactured (see FIG. 4A).

In step S102, a coating film 210 is formed on the surface of the base member 200 of the quartz cover ring 26 (see FIG. 4B). The coating film 210 is formed of a film having a higher adhesiveness to the deposited reaction by-products than that of a quartz member, and/or the coating film 210 is formed of a film that inhibits the deposition of reaction by-products as compared to quartz members.

Here, the coating film 210 is formed so as to cover the entire surface exposed to the plasma-generating space (i.e., inner space 10s) when the cover ring 26 is disposed in the etching processing apparatus 1. The coating film 210 is formed across regions 301 and 302 to be described later in FIGS. 5A to 5C.

The coating film 210 is made of a different material than quartz and has a film thickness of 10 nm and more and less than 800 nm.

The coating film 210 is composed of light elements that are easily discharged from the inner space 10s by the exhaust device 50 when the light elements are removed by a seasoning process described below. Preferably, however, the coating film 210 does not include elements (e.g., Al) that may be a source of contamination to the substrate W. Specifically, the coating film 210 is made of a film consisting of any one or more elements of C, Si, F, N, O, or B. More specifically, the coating film 210 is preferably any of SiC, Si₃N₄, B₄C, and C (carbon film).

A desired thin film can be formed by deposition of any one of ALD, PVD, and CVD.

In step S103, a cover ring 26 is disposed on the etching processing apparatus 1. The above-described steps S101 and S102 are also referred to as a cover ring manufacturing process. Moreover, step S104 and Step S105 below are also referred to as a cover ring operation process.

In step S104, a seasoning process of the etching processing apparatus 1 is performed. In the seasoning process, a seasoning gas (process gas) is supplied from the gas source group 40 to the inner space 10s, a plasma is generated within the inner space 10s, and the seasoning process of the etching process apparatus 1 is performed.

FIG. 5A illustrates an example of a cross-sectional view of a cover ring 26 in the seasoning process performed by the etching processing apparatus 1. By generating a plasma 300 in the inner space 10s, the coating film 210 is lost by the seasoning process in the region 301 near the plasma 300. In contrast, the coating film 210 remains in the region 302 distant from the plasma 300. Here, if the coating film 210 is thick, the coating film 210 of the region 301 may not be lost by the seasoning process but may be lost in subsequent substrate processing (etching). Because the surrounding environment of the substrate W changes before and after the loss of the coating film 210 of the region 301, substrate processing may be affected. Therefore, the coating film 210 is preferably a thin film. Preferably, the thickness of the coating film 210 in the region 301 is less than 800 nm, which may be reliably lost by the seasoning process. However, if the coating film 210 is too thin, the base member 200 may be exposed without sufficient coating in the region 302. In order to provide sufficient coating without exposure of the base member 200, the coating film 210 preferably has at least a thickness of 10 nm. Therefore, the coating film 210 is preferably made a thin film of 10 nm or more and less than 800 nm. This allows the coating film 210 of the region 301 to be rapidly lost, and sufficient coating can be formed in the region 302 so that the base member 200 is not exposed.

In step S105, substrate processing of the etching processing apparatus 1 is performed. In the substrate processing, a substrate W is conveyed into the chamber 10 and mounted on a stage 14. An etching gas (process gas) is supplied from the gas source group 40 to the inner space 10s to generate a plasma within the inner space 10s to etch the substrate W supported on the stage 14.

Here, the region 301 near the plasma 300 is the region where the etch rate of the reaction by-product adhered to the surface of the cover ring 26 is higher than the deposition rate of the reaction by-product. On the surface of the cover ring 26 in the region 301, the adhered reaction by-products are etched by plasma, and the surface of the cover ring 26 is kept exposed. The region 302 outside the region 301 is also the region where the etch rate of the reaction by-product adhered to the surface of the cover ring 26 is lower than the deposition rate of the reaction by-product. On the surface of the cover ring 26 in the region 302, the surface of the cover ring 26 is covered by the attached reaction by-products.

FIG. 5B illustrates an example of a cross-sectional view of a cover ring 26 in an initial state of substrate processing. FIG. 5C illustrates an example of a cross-sectional view of a cover ring 26 in a later stage of substrate processing. Here, a reaction by-product film 350 is formed due to deposition of a reaction by-product on a coating film 210 in a region 302 where a deposition rate of the reaction by-product is higher than an etch rate of the reaction by-product.

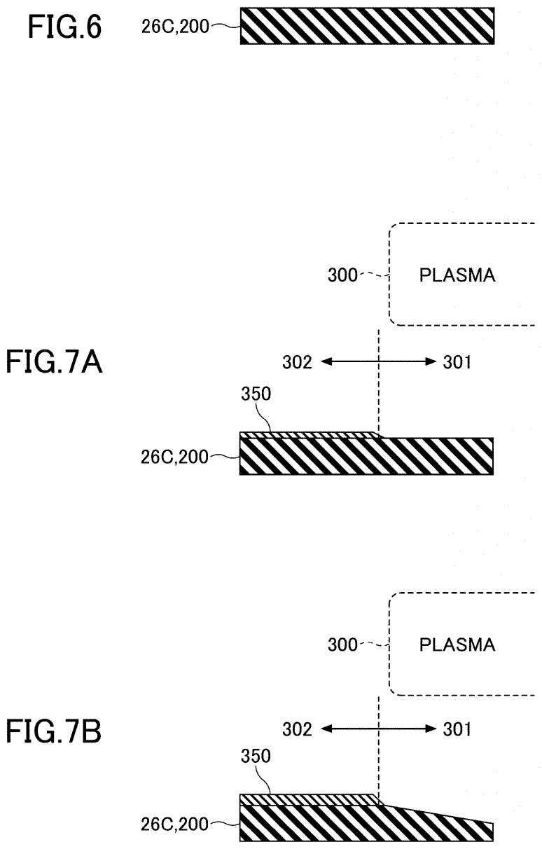

Here, a cover ring 26C according to a reference example will be described with reference to FIGS. 6, 7A and 7B. FIG. 6 is an example of a cross-sectional view of a cover ring 26 when the cover ring 26C according to the reference example is manufactured. FIGS. 7A and 7B are examples of a cross-sectional view of the cover ring 26 according to the reference example in operation. FIG. 7A illustrates an example of a cross-sectional view of a cover ring 26C in an initial state of substrate processing. FIG. 7B illustrates an example of a cross-sectional view of a cover ring 26C in a late stage of substrate processing.

As illustrated in FIG. 6, the cover ring 26C according to the reference example is formed of a base member 200. That is, the cover ring 26C according to the reference example differs from the cover ring 26 according to the present embodiment in that the cover ring 26C does not have a coating film 210. Also, the manufacturing process in the cover ring 26C does not include step S102.

In the operation process of the cover ring 26C of the reference example, a reaction by-product film 350 is deposited on the area 302 of the cover ring 26C from the initial state of substrate processing, as illustrated in FIG. 7A. Then, as illustrated in FIG. 7B, the film thickness of the reaction by-product film 350 increases in the later stage.

Here, the effect of the cover ring 26 according to the present embodiment will be described while comparing the cover ring 26 of the present embodiment with the cover ring 26C according to the reference example.

### First Example

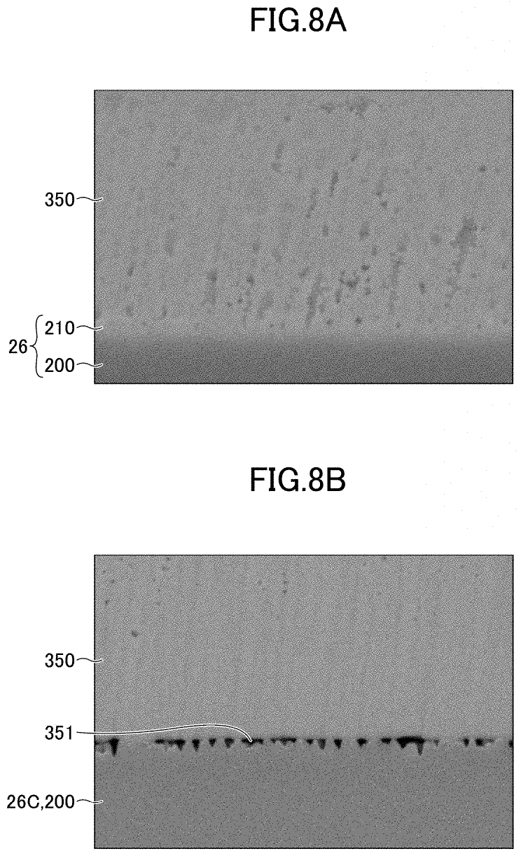

In a first example, an etching process was performed on a substrate W using a gas diluted with CF₄/O₂ as an etching gas of an etching processing apparatus 1. Thus, a reaction by-product film 350 was deposited on a region 302 of a cover ring 26 having a coating film 210 of SiC according to the present embodiment and a cover ring 26C without a coating film 210 according to the reference example. FIGS. 8A and 8B are examples of a cross-sectional view of a cover ring after a reaction by-product film 350 was formed. FIG. 8A shows a first example of a cover ring 26 in accordance with the present embodiment. FIG. 8B shows a cover ring 26C of a reference example.

In this gas condition, as shown in FIG. 8B, in the cover ring 26C, a void 351 is formed at the boundary between the cover ring 26C and the reaction by-product film 350 according to the reference example. Therefore, the adhesiveness between the cover ring 26C and the reaction by-product film 350 decreases, and peeling of the reaction by-product film 350 may occur.

In contrast, as shown in FIG. 8A, in the covering ring 26 of the first example, no void was observed at the boundary between the cover ring 26 and the reaction by-product film 350. That is, in the cover ring 26 of the first example, the adhesiveness between the cover ring 26 and the reaction by-product film 350 is improved. Therefore, it is possible to inhibit peeling of the reaction by-product film 350.

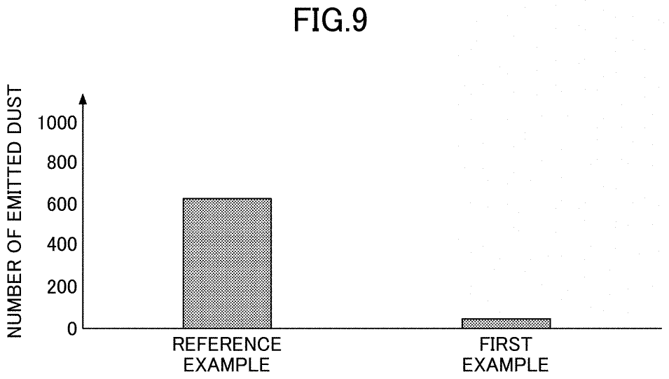

FIG. 9 is an example of a graph explaining the number of emitted dusts in a cover ring 26 having a coating film 210 of SiC of the first example and the covering ring 26C without the coating film 210 of the reference example. Here, the particle number of the peeled/ground reaction by-product was measured by emitting an ultrasonic radiation wave to the cover ring 26 of the first example on which the reaction by-product film 350 is deposited and the covering ring 26C of the reference example.

As shown in FIG. 9, the cover ring 26 of the first example indicates that the adhesiveness between the coating film 210 and the reaction by-product film 350 can be improved by providing the coating film 210, and that the particle number of the reaction by-product can be reduced.

### Second Example

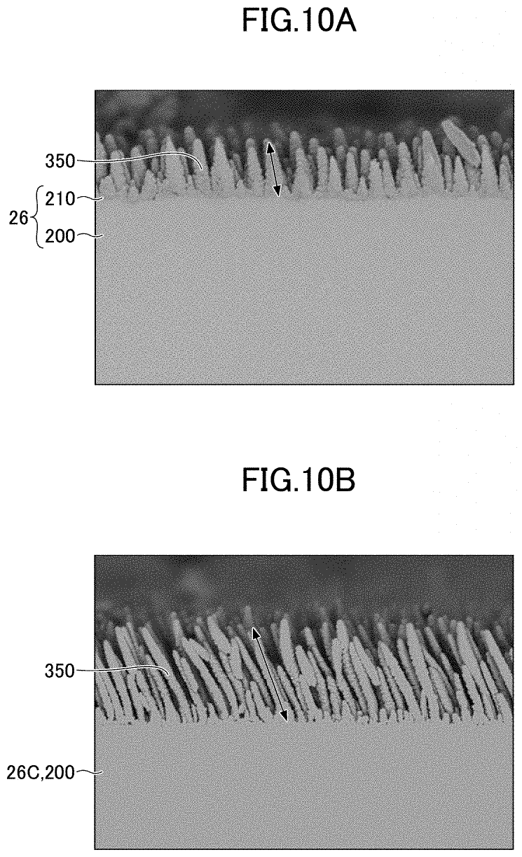

In a second example, an etching process was performed on a substrate W using a diluted CF-based/O₂ gas as an etching gas of the etching processing apparatus 1. Thus, a reaction by-product film 350 was deposited on an area 302 of a cover ring 26 of the second example and a cover ring 26C of a reference example. FIGS. 10A and 10B are examples of a cross-sectional view of a cover ring after a reaction by-product film 350 is formed thereon. FIG. 10A shows the second example of a cover ring 26 having a coating film 210 of SiC. FIG. 10B shows the reference example of a cover ring 26C without a coating film 210.

In this gas condition, column-shaped reaction by-products are formed, as shown in FIGS. 10A and 10B. Comparing the sizes of the column-shaped reaction by-products, in the cover ring 26C of the reference example shown in FIG. 10B, long and having slightly larger tips column-shaped reaction by-products are formed. As a result, the column-shaped reaction by-products are likely to break, and the reaction by-products are liable to scatter and to emit dust.

In contrast, in the cover ring 26 of the second example shown in FIG. 10A, short, thick root and narrow tip column-shaped (cone-shaped) reaction by-products are formed. For this reason, the column-shaped reaction by-products are unlikely to break, and the reaction by-products can be prevented from scattering and emitting dust.

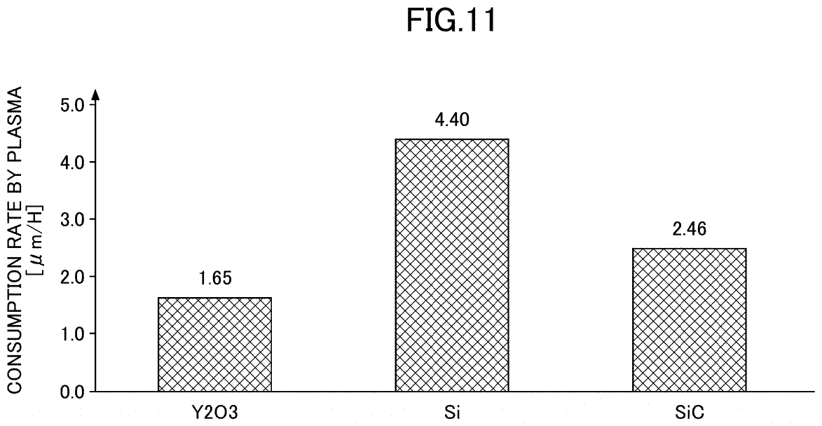

Next, the loss of the coating film 210 in the seasoning process will be described with reference to FIG. 11. FIG. 11 is an example of a graph showing a consumption rate due to plasma. FIG. 11 shows consumption rates due to plasma of Y₂O₃ used as a highly plasma resistant protective film, Si used as the base member 200, and SiC as an example of the coating film 210.

The coating film 210 has a higher consumption rate than that of the protective film (Y₂O₃). Thus, the coating film 210 in the region 301 can be rapidly removed. Here, when the surface exposed to the inner space 10s during substrate processing (S105) is changed from SiC (coating film 210) to Si (base member 200), the substrate processing may be affected. The cover ring 26 of the second example can quickly remove the coating film 210 in the region 301 during the seasoning, thereby reducing the effect on the substrate processing.

The boundary between the region 301 and the region 302 varies depending on a process condition. In contrast, the coating film 210 on the region 301 can be removed by performing the seasoning process of step S104 on the cover ring 26, which is entirely covered with the coating film 210.

Although the embodiments of the etching processing apparatus 1 have been described, the present disclosure is not limited to the above-described embodiments, and various modifications and alternations can be made within the scope of the spirit of the present disclosure described in the claims.

An annular quartz member having a surface covered with a coating film 210 is illustrated by citing an example of a cover ring 26, but is not to the limitation. A coating film may be formed on a surface of an a member that is an annular member (protection ring) disposed above the stage 14.

Thus, as discussed above, an embodiment of the present disclosure can provide an etching processing apparatus, a quartz member and a plasma processing method that can reduce generation of a particle.

All examples recited herein are intended for pedagogical purposes to aid the reader in understanding the disclosure and the concepts contributed by the inventor to furthering the art, and are to be construed as being without limitation to such specifically recited examples and conditions, nor does the organization of such examples in the specification relate to a showing of the superiority or inferiority of the disclosure. Although the embodiments of the present disclosure have been described in detail, it should be understood that various changes, substitutions, and alterations could be made hereto without departing from the spirit and scope of the disclosure.

What is claimed is:

1. An etching processing apparatus, comprising:
a stage configured to receive a substrate;
a chamber configured to contain the stage;
a plasma generator configured to generate plasma in the chamber;
an annular quartz member disposed in a space in which the plasma is generated, the annular quartz member including a surface facing the space; and
a coating film covering the surface of the quartz member,
wherein the coating film is made of a material other than quartz, and has a thickness of 10 nm or more and less than 800 nm.

2. The etching processing apparatus as claimed in claim 1, wherein the coating film is made of a compound consisting of any two or more elements of C, Si, F, N, O and B.

3. The etching processing apparatus as claimed in claim 2, wherein the coating film is composed of any one of SiC, Si₃N₄, and B₄C.

4. The etching processing apparatus as claimed in claim 3, wherein the coating film is composed of SiC.

5. The etching processing apparatus as claimed in claim 1, further comprising:
an edge ring disposed to surround the substrate,
wherein the annular quartz member is disposed to surround the edge ring.

6. The etching processing apparatus as claimed in claim 1, further comprising:
an upper electrode disposed above the stage,
wherein the annular quartz member is disposed above the stage and is configured to support the upper electrode.

7. The etching processing apparatus as claimed in claim 1, wherein the coating film is formed by any one of ALD, PVD and CVD.

8. An annular quartz member used for an etching processing apparatus including a stage configured to receive a substrate, a chamber configured to contain the stage, and a plasma generator configured to generate plasma in the chamber, the annular quartz member being disposed in a space in which the plasma is generated, the annular quartz member comprising:
an annular base member made of quartz, the annular base member including a surface facing the space; and
a coating film covering the surface of the annular base member,
wherein the coating film is made of a material other than quartz, and has a thickness of 10 nm or more and less than 800 nm.

9. The annular quartz member as claimed in claim 8, wherein the coating film is made of a compound consisting of any two or more elements of C, Si, F, N, O and B.

10. The annular quartz member as claimed in claim 9, wherein the coating film is composed of any one of SiC, Si₃N₄, and B₄C.

11. The annular quartz member as claimed in claim 10, wherein the coating film is composed of SiC.

12. The annular quartz member as claimed in claim 8, wherein the coating film is formed by any one of ALD, PVD and CVD.

13. An etching processing method, comprising steps of:
forming a coating film on an annular quartz member, the coating film having a thickness of 10 nm or more and less than 800;
attaching the annular quartz member to an etching processing apparatus;
removing part of the coating film on the annular quartz member by generating plasma in the etching processing apparatus;
carrying a substrate into the etching processing apparatus; and
etching the substrate.

14. The plasma processing method as claimed in claim 13, wherein the coating film is made of a compound consisting of any two or more elements of C, Si, F, N, O and B.

15. The plasma processing method as claimed in claim 14, wherein the coating film is composed of any one of SiC, Si₃N₄, and B₄C.

16. The plasma processing method as claimed in claim 15, wherein the coating film is composed of SiC.

17. The etching processing method as claimed in claim 13, further comprising:
an edge ring disposed to surround the substrate,
wherein the annular quartz member is disposed to surround the edge ring.

18. The etching processing method as claimed in claim 13, further comprising:
an upper electrode disposed above the stage,
wherein the annular quartz member is disposed above the stage and is configured to support the upper electrode.

19. The plasma processing method as claimed in claim 13, wherein the coating film is formed by any one of ALD, PVD and CVD.

20. The plasma processing method as claimed in claim 13, wherein the removing part of the coating film on the annular quartz member comprises removing the coating film on an inner peripheral side of the annular quartz member.
